(19) United States
(12) Patent Application Publication
(10) Pub. No.: US 2004/0153908 A1
(43) Pub. Date: Aug. 5, 2004

(54) System and method for controlling information exchange, privacy, user references and right via communications networks communications networks

(75) Inventors: Vincent J. Schiavone, Berwyn, PA (US); David I. Brussin, Berwyn, PA (US)

Correspondence Address: SYNNESTVEDT & LECHNER, LLP, 2600 ARAMARK TOWER, 1101 MARKET STREET, PHILADELPHIA, PA, 191072950

(73) Assignee: ePrivacy Group, Inc., Paoli, PA

(21) Appl. No.: 10/657,849

(22) Filed: Sep. 9, 2003

Related U.S. Application Data
(60) Provisional application No. 60/409,558, filed on Sep. 9, 2002.

(51) Int. Cl. G01R 31/28

(52) U.S. Cl. 714/712

(57) ABSTRACT

A Data Controller stores information in a secure vault and establishes rules for retrieval of information therefrom, subsequent use of such information, etc. Requests for information carry terms governing the subsequent use of such information. Any discrepancies in terms may be resolved by negotiation until agreement is reached. Requested information is retrieved only if the terms are in accord. The agreed-upon terms governing use of the information remain associated with the information, e.g. with the requesting party or any third parties to which the information is later transferred. Interfaces may be provided to later allow the Data Controller to access, modify and update any of its disclosed information or the associated terms of use. Accordingly, compliance with the original terms of disclosure can be ensured even after relinquishment of information to requesting parties, or third parties. Authentication of the information or requests therefor may be verified by an independent party.

### CROSS-REFERENCE TO RELATED APPLICATION

This application claims the benefit of U.S. Provisional Patent Application No. 60/409,558, filed Sep. 9, 2002.

### FIELD OF THE INVENTION

The present invention relates generally to the field of information exchange by data transmission in communications networks, and particularly to a system and method providing enhanced control to information proprietors over disclosure, collection, distribution and use of their proprietary information by others.

### DISCUSSION OF THE RELATED ART

Electronic and/or computerized communications networks, such as the Internet, are widely used for information exchange, e.g. by sending and receiving electronic mail (“e-mail”) messages, instant messaging, display of and/or interaction with World Wide Web pages, display of advertisements within such e-mail messages and/or Web pages, conducting electronic commerce transactions for purchases and sales of goods, and distribution of computer files such as textual, image, audio and/or video files, etc.

In many instances, the information exchanged is considered proprietary, confidential, sensitive, private, semi-private or personal (collectively “proprietary and/or personal”) information. For example, in the context of personal privacy, an individual may disclose personally identifiable information (PII) such as a full name, home address, social security number, credit card number, etc. Such information is disclosed in a certain context, for a certain purpose, e.g. for the purchase of a book via a website, to access an online banking account, etc. However, after this proprietary and/or personal information is disclosed to the information requester, e.g. book seller or banking website, although the individual may indicate a use and onward transfer preference and/or the requestor may have a privacy policy or statement regarding use and promises made to the individual, the individual loses actual control over how that information is used by the information requestor and/or how or whether that information is distributed to third parties, and/or the expiration of any permission granted. Such unfettered use of proprietary and/or personal information is contrary to fundamental principles of personal privacy.

In addition, some proprietary and/or personal information in these electronic distribution and/or exchange interactions is collected passively, without notice to the individual or knowledge of the individual, and used for purposes unknown and/or unauthorized by the individual.

Various classes of proprietary and/or personal information have, or can be assigned, sets of principles governing the accepted practice of handling of that information. For example, in the context of digital rights management, an appropriate set of principles might be derived largely from applicable copyright and/or contract laws. By way of further example, there are some well-known principles for privacy-sensitive handling of personally identifiable information (PII), such as, in the United States, the Fair Information Practice Principles (FIPPs), and in the European Union and many other countries worldwide, the guidelines of the Organization for Economic Cooperation and Development (OECD). The Fair Information Practice Principles originate from a report to Congress presented by the U.S. Department of Health, Education, and Welfare in 1973, and have since been the guiding principles that have been utilized in the U.S. regarding the fair collection, usage and storage of personal, proprietary and other data. For example, the Fair Information Practice Principles provide four core principles, namely, notice, choice, access and security, while enforcement is often listed as an important related mechanism for ensuring compliance with promises made by the data collector to the data provider. In the EU, the OECD identified in 1980 in its “Guidelines on the Protection of Privacy and Trans-Border Flows of Personal Data” seven principles of privacy protection (that substantively are quite similar to the Fair Information Practice Principles). These principles are: (1) Notice, providing for notice about the purposes for which data is collected and used; (2) Choice, permitting opt-out at any stage for various uses of the collected data; (3) Onward Transfer, providing that any third party must abide by notice and choice principles in connection with transfer of collected data onward to other parties; (4) Access, providing the ability to access collected data to correct, amend, or delete inaccurate information; (5) Security, providing that reasonable precautions must be taken to protect from loss, misuse and unauthorized access, disclosure, alteration and destruction of collected data; (6) Data integrity, providing that the data collected must be (i) relevant for the purposes used and (ii) reliable for its intended use (accurate); and (7) Enforcement, for ensuring compliance, there must be affordable independent recourse mechanisms.

As an example of how the Fair Information Practice Principles may come into play in the US, under the Fair Information Practice Principles, at the time of collection of personal information a company should provide a customer/website user with a statement setting forth notice of information being collected, intended uses of the information being collected, the choice the customer/user has regarding such uses, the security under which the information is to be maintained and the rights that the customer website user will have to access and review, update and delete such information. Although the Fair Information Practice Principles are widely accepted in the US as a basis for the information businesses should provide customers in written form (i.e., generally in privacy policies) when collecting, using, storing and disclosing/sharing information regarding its customers, at present, there is no analog in the electronic communications context to electronically, automatedly and/or anonymously regulate, negotiate and manage such processes. By way of example, age and consent registrations and elections for onward transfer of customer information are typically performed manually and repetitively in non-standardized fashion, often leading to consumer confusion, mistakes and dissatisfaction. Additionally, the present lack, in the electronic communications context, of proper notice about collection of information compromises an individual's ability, as an information proprietor, to make informed decisions about whether to disclose the requested information. The lack of dynamic derivation of information compromises the individual's ability to disclose the minimum amount of data necessary for a given purpose. There is typically no tracking of collected information, which prevents parties receiving data from complying with their own policies, commitments and obligations regarding collected information. A lack of interfaces prevents individuals from exercising their rights, e.g. those relating to access, choice, enforcement, etc. under the Fair Information Practice Principles.

By way of further example, many e-commerce and other websites collect personally identifiable information (PII) from individuals during e-commerce transactions or otherwise, but fail to allow the individual, as the data subject, to access, update and/or limit the use of the collected information. This is contrary to established Fair Information Practice Principles, contrary to basic principles of personal privacy, and fails to provide individuals with adequate control over information relating to them.

In the context of digital rights management, proprietary information may include data files embodying copyright protected computer software, music or other audio files, movies or other video files, textual, etc. An owner of a proprietary interest in such proprietary information does not want to lose control over how its proprietary information is distributed and/or exchanged. In particular, the owner would like to control distribution such that the information is distributed pursuant to the owner's terms, which may include a payment for receipt of the information.

### SUMMARY

The present invention provides a system and method for providing information proprietors enhanced control over disclosure, collection, distribution and use of their proprietary and/or personal information by others, and thereby facilitates information exchange in accordance with Fair Information Practice and Procedures and OECD guidelines. In other words, an information proprietor is referred to herein as a “Data Controller” and is empowered with control over its proprietary and/or personal information. Accordingly, a Data Controller is any individual, corporate, organizational or other rights owner, controller or subject of proprietary and/or personal information. In accordance with the present invention, a Data Controller maintains a Data Vault in which proprietary and/or personal information is securely stored. The Data Vault is a local, remote/network and/or chip-based repository for storing data elements representing the proprietary and/or personal information. Data elements in the Data Vault are accessed for local use and/or for disclosure to Data Requestors only in accordance with Rules established and/or accepted by the Data Controller.

As used herein, a Data Requestor is any individual, corporation, enterprise, organization or other party requesting information from a Data Controller, e.g. via an electronic communication via a communications network. Information Requestors provide an Information Request including a declarative statement providing notice of what information is requested (i.e. data elements), as well as notice of the use(s) for which the information is requested. The terms “use” and “use(s)” are used broadly herein to include uses, terms, conditions, commitments, obligations, policies, etc. associated with the access, disclosure and handling of the requested information. An automated negotiation process occurs by which the Data Controller's Data Vault is accessed only if the use terms of the declarative statement are in accord with the Rules established by the Data Controller for access of information.

The Information Request may have various forms. Optionally, the Information Request identifies a definition, which may include logic, information for a dynamic lookup, etc., for interacting with various data elements to dynamically create a suitable response to the Information Request by deriving a response information from data elements already stored in a manner prescribed by the definition. In this manner, an Information Response may be given without disclosing underlying data so that the least amount of information required for an acceptable response is disclosed to an outside party by a Data Controller in response to an Information Request. Alternatively, definitions may be stored in a Definitions database of the Data Controller Agent, or elsewhere.

Any discrepancies between an Information Request and the Rules may result in a negotiation process between the Data Requestor and the Data Controller whereby originally proposed terms of use are modified and/or substituted until agreeable terms are reached to ensure that the information is disclosed only on terms agreeable to the Data Controller. More specifically, the negotiation process may be carried out in an automated fashion by a Negotiation Engine of the Data Controller Agent and a similar Negotiation Engine of the Data Requestor. For example, a hierarchical approach defining a preferred term, first alternative term, next alternative term, etc. that may be followed until agreement is reached or all available options are exhausted. Alternatively, for example, the Data Controller's terms may be accepted if the Data Requestor's terms are rejected. In effect, a contract is formed between the Data Requestor and the Data Controller regarding disclosure, collection, distribution and use of information. The inventive system facilitates compliance with the terms of that contract by the Data Requestor.

Information disclosed and stored remotely by a Data Requestor is stored in association with an identification of the terms and conditions under which the Data Collector's information was disclosed such that information may be retransmitted from the Data Requestor and/or subsequently used by the Data Requestor only in accordance with the terms and conditions. Such terms and conditions of use are stored in the form of data as commonly recognized and standardized tags (“Preference Tags”). Any transmission to a Third-Party Data Requestor from the Data Requestor also carries Preference Tags indicating the terms of use permitted by the Data Controller at the time the information was originally disclosed. The Data Requestor, Third-Party Data Requestor and Data Controller all maintain Transaction Logs identifying the information disclosed, to which parties, and the applicable terms and conditions for use of the disclosed information.

Optionally, an Independent Trust Authority, such as TRUSTe, Verisign or other trustworthy parties that perform auditing functions (e.g. accounting firms, privacy consultants, etc.) may authenticate and/or digitally sign Information Requests from Data Requestors to verify that the notice and use provisions encapsulated in the Information Requests are accurate and/or that the information provided by the Data Controller is accurate so that such Information Requests can be made and answered with a high degree of trustworthiness, as enabled by the Independent Trust Authority. While the present invention enables self-regulatory trust assurances, use of an Independent Trust Authority provides verifiable historical compliance with the information collection, use, storage and disclosure terms and condition for each data element, as appropriate.

This application relates to subject matter disclosed in U.S. patent application Ser. No. 09/793,233 entitled “System And Method For Conducting Predefined Transactions Via an Electronic Mail Messaging Infrastructure,” and U.S. application Ser. No. 09/793,263 entitled “System and Method for Rule-based Processing of Electronic Mail Messages,” both filed Feb. 26, 2001, the entire disclosures of both of which are hereby incorporated herein by reference.

### BRIEF DESCRIPTION OF THE DRAWINGS

FIG. 1 is an example of a network system in accordance with the present invention.

FIG. 2 shows a block diagram of an exemplary computer that may be configured with appropriate software in accordance with the present invention as any server or client computer of FIG. 1.

FIG. 3 shows a block diagram showing logical components of software that may be stored and executed in the memory of the device of FIG. 2 and that may be configured for use in accordance with the present invention.

FIG. 4 is a flow diagram showing information exchange in accordance with an exemplary embodiment of the present invention, shown from a Data Controller perspective.

FIG. 5 is a flow diagram showing use of maintenance interfaces to exercise post-disclosure control over proprietary and/or personal information in accordance with an exemplary embodiment of the present invention, shown from the Data Controller perspective.

FIG. 6 is a flow diagram showing the information exchange of FIG. 4 from a Data Requestor perspective.

FIG. 7 is a flow diagram showing information exchange between a Data Requestor and a Third Party Data Requestor in accordance with an exemplary embodiment of the present invention.

FIG. 8 is a flow diagram showing use of maintenance interfaces to implement post-disclosure control over proprietary and/or personal information in accordance with an exemplary embodiment of the present invention, shown from the Data Requestor perspective.

FIG. 9 is a flow diagram showing an exemplary embodiment of participation of an Independent Trust Authority in an information exchange in accordance with FIGS. 1-8.

### DETAILED DESCRIPTION

Conceptually, the present invention provides any individual, organization or other data subject to which information pertains, or any entity having control over information (collectively, a Data Controller) with enhanced control over disclosure, collection, distribution and/or use of such information by any individual, corporation, enterprise, organization or other party requesting information from a Data Controller, or more specifically a hardware and/or software-implemented process acting on behalf thereof (collectively, a Data Requestor), e.g. via an electronic communication via a communications network by retailers, service providers, or other organizations. The Data Controller controls how and whether its proprietary and/or personal information is used by setting forth Rules (such rules can be developed by explicit instructions of the user, observed behavior or one or more methods that the Data Controller selects) embodying the terms and conditions of use for which the Data Controller agrees to permit access to its proprietary and/or personal information, e.g. for retrieval for local use, for disclosure to an outside party, or for retrieval for dynamic derivation of information for local use or disclosure to an outside party. The Data Controller Agent, i.e. a hardware or software-implemented process operating on behalf of a Data Controller, determines whether to disclose the Data Controller's proprietary and/or personal information by interpreting Information Requests and comparing the Rules with declarative statements of the Information Request providing notice of the information requested and terms of use for such information. Permitted uses for collected proprietary and/or personal information travel via Preference Tags associated with the collected information to Data Requestors to ensure continued compliance with same by Data Requestors, and further travel onward from Data Requestors to any Third Party Data Requestors (a third party Data Requestor or more specifically a hardware and/or software-implemented process acting on behalf thereof) to ensure continued compliance with the terms of use under which the proprietary and/or personal information was originally disclosed by the Data Controller, i.e. by the Data Controller Agent on behalf of the Data Controller.

The Data Controller is provided with ongoing access, either directly or indirectly, to third party databases having received and stored its proprietary and/or personal information, and is provided with the ability to modify terms of use (Choice, in the context of Fair Information Practice Principles) for such proprietary and/or personal information, or to modify such information or characteristics of such information (Access in the context of Fair Information Practice Principles), even after such information is disclosed to and stored by such third parties, through an electronic communications interfaces in accordance with the present invention.

Accordingly, the Data Controller is given enhanced control over its information in accordance with its preferences and/or generally accepted information exchange principles governing the type of information exchanged, such as Fair Information Practice Principles for PII in the personal privacy context, or copyright/contract principles in the digital resource management context.

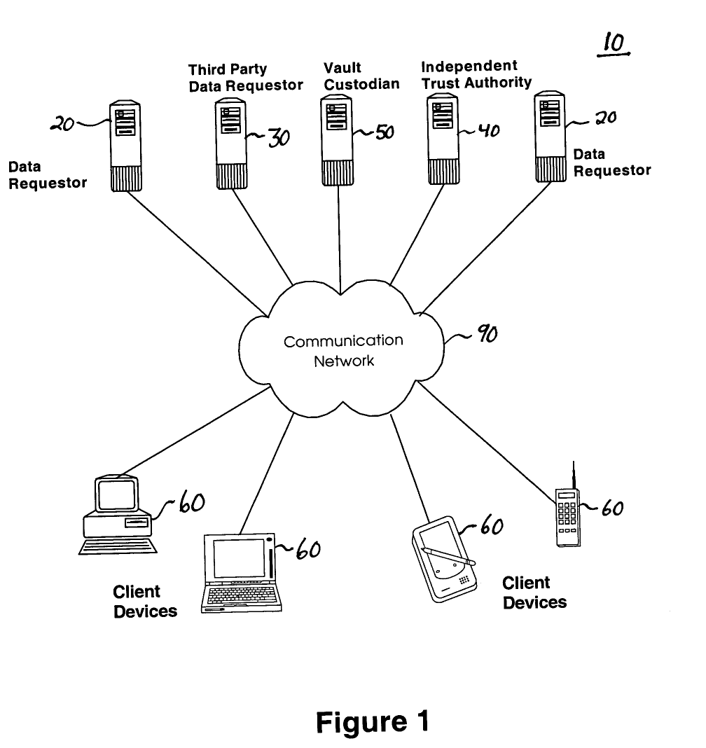

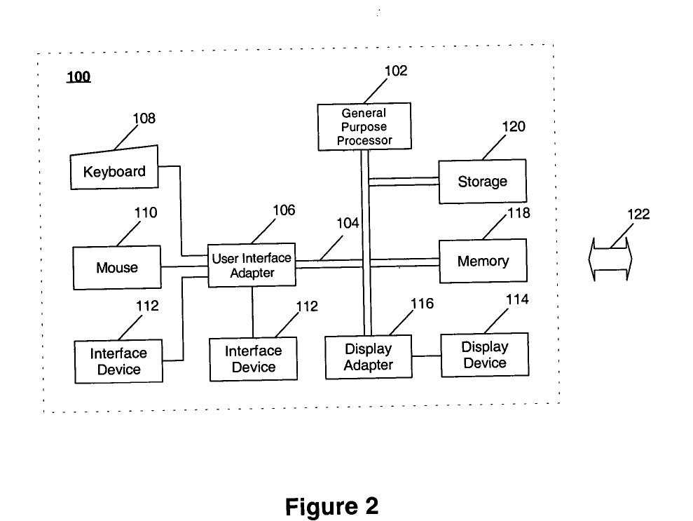

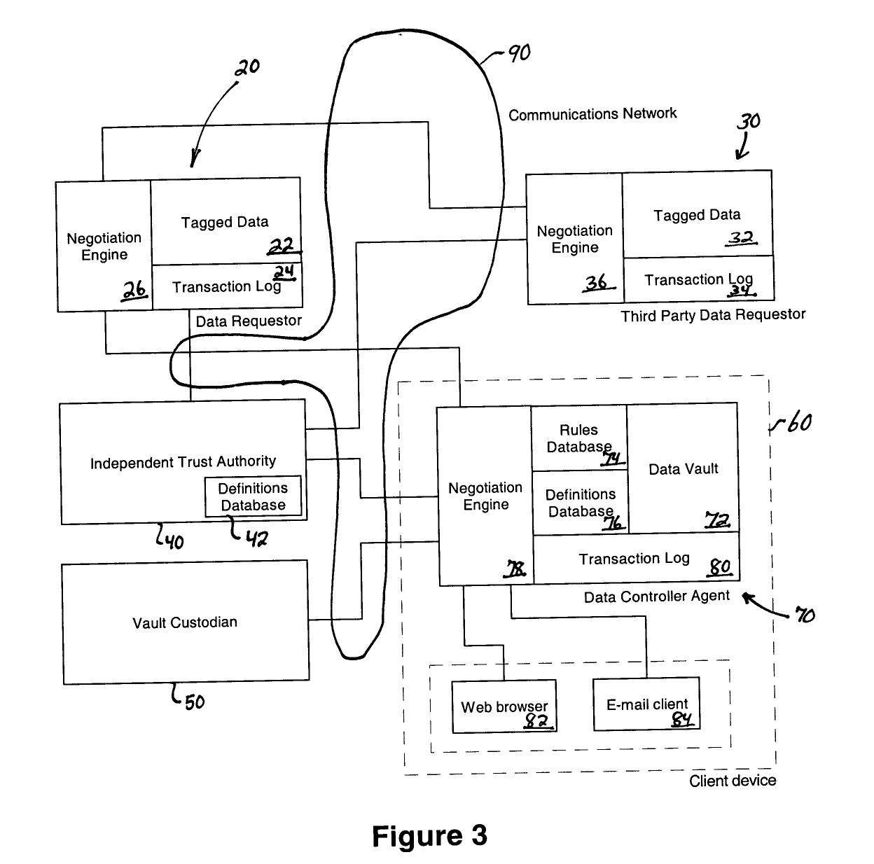

FIG. 1 is an example of a network system 10 including a Data Requestor server computer 20, a Third Party Data Requestor server computer 30, an Independent Trust Authority server computer 40, a Vault Custodian server computer 50 and Data Controller Agent client computers 20 interconnected via a communications network 90. Hardware, software and communication for enabling network-based communications between such devices is well-known in the art. Such computers include hardware of a type generally known in the art (as discussed below with reference to FIG. 2), but configured with software for carrying out the present invention, as discussed below with reference to FIGS. 3-9.

FIG. 2 shows a block diagram of an exemplary computer that may be configured with appropriate software in accordance with the present invention as any server or client computer in accordance with FIG. 1. As is well known in the art, the information processing system 100 of FIG. 2 includes a general purpose microprocessor (CPU) 102 and a bus 104 employed to connect and enable communication between the microprocessor 102 and the components of the information processing system 100 in accordance with known techniques. The information processing system 100 typically includes a user interface adapter 106, which connects the microprocessor 102 via the bus 104 to one or more interface devices, such as a keyboard 108, mouse 110, and/or other interface devices 112, which can be any user interface device, such as a touch sensitive screen, digitized entry pad, etc. The bus 104 also connects a display device 114, such as an LCD screen or monitor, to the microprocessor 102 via a display adapter 116. The bus 104 also connects the microprocessor 102 to memory 118 and long-term storage 120 (collectively, “memory”) which can include a hard drive, diskette drive, tape drive, etc.

The information processing system 100 may communicate with other computers or networks of computers, for example via a communications channel, network card or modem 122. The information processing system 100 may be associated with such other computers in a local area network (LAN) or a wide area network (WAN), or the information processing system 100 can be a client or server in a client/server arrangement with another computer, etc. All of these configurations, as well as the appropriate communications hardware and software, are known in the art.

Software programming code for carrying out the inventive method is typically stored in memory. Accordingly, the information processing system 100 stores in its memory microprocessor executable instructions for carrying out the present invention.

FIG. 3 shows a block diagram showing logical components of software that may be stored and executed in the memory (118, 120) of the device of FIG. 2 and that may be configured for use in accordance with the present invention. Referring now to FIG. 3, a Data Controller Agent 70 (an agent process for the Data Controller's client device 60), a Vault Custodian 40 (a remote server of the Data Controller Agent 70, portions thereof, or a party controlling access thereto), an Independent Trust Authority (an independent party for verifying information of Data Controller and/or Information Requests of Data Requestors, etc.), a Data Requestor 20 (requesting information from Data Controllers via the Data Controller Agent 70), and a Third Party Data Requestor 30 (requesting information from Data Requestors 20) in accordance with the present invention are shown.

The Data Controller Agent 70 is an agent process operated by or on behalf of a Data Controller, the Data Controller being any individual, organization or other data subject to which information pertains, or any entity having control over information. The Data Controller Agent 70 may be implemented on a conventional client device 60 using software to specially configure the client device 60 (i.e. any network communications device such as a desktop computer, notebook computer, personal digital assistant (PDA) type device, or Web/Internet enabled wireless telephone) to provide various logical components.

As shown in FIG. 3, these logical components of the Data Controller Agent 70 include a Data Vault 72 which is a database, memory or other repository for securely storing data elements representing proprietary and/or personal information under the control of the Data Controller. In the context of personal privacy, such information may include data elements representing the Data Controller's name, address, telephone number, e-mail address, credit card number, social security number or other personally identifiable information (PII). Alternatively, in the context of digital rights management, such information may include data elements in the form of data files embodying movies, music, photographs or other audio, video, image or text files, etc. For example, information may be entered and stored in the Data Vault 72 using an interface of a type generally known in the art for collecting data from a user, e.g. via a web or network-based graphical user interface. Data elements stored in the Data Vault 72 are secured by encryption and/or other techniques to prevent unauthorized retrieval or disclosure of data elements stored therein.

It should be noted that consumer information and preferences, not just proprietary and/or personal information and preferences, may also be stored in the Data Vault 72. For example, such consumer information and preferences may include likes, dislikes, tastes, interests, hobbies, etc. so that anonymous and automated customized or personalized content and experiences, including targeted and direct marketing, can be performed in accordance with the present invention by using such information retrieved from the Data Vault 72, but with the appropriate permission of the Data Controller, as established by the Data Controller's rules/preferences for access and use/disclosure of information retrieved from the Data Vault 72, as discussed below with reference to the Rules database.

The individual data elements stored in the Data Vault 72 are preferably described and/or defined by a widely accepted schema so that multiple Data Controllers store data elements in compliance with the schema. Preferably, information is stored in the Data Vault 72 in a very granular and related fashion so that disclosure of combinations of data bits may be individually tracked. For example, rather than store a birthdate in month, day and year format, it may be advantageous to store information as a first data element identifying a birth month, another data element identifying a birth day, and yet another data element identifying a birth year. In this manner, each discrete data element may be used in a granular manner to satisfy a request for data by disclosing only a minimal amount of information.

The Data Controller Agent 70 also includes a Rules database 74 is a repository for information setting forth the terms and conditions under which the Data Controller is agreeable to retrieving and/or disclosing data elements stored in the Data Vault 70. Such information may be entered and stored in the Rules database 74 using a graphical user interface. For example, a Data Controller may specify via the rules of the Rules database 74 that any data elements stored in the Data Vault 70 may be retrieved for local use (i.e. on the PC, PDA, web-enabled wireless device, etc. being used by the Data Controller) to personalize a web page displayed via the Data Controller's web browser, that the Data Controller's e-mail address data element may be communicated to any Data Requestor for any purpose, that the Data Controller's home address data element may be communicated to any Data Requestor for any purpose except redistribution by the Data Requestor to Third Party Data Requestors, and that the Data Controller's credit card number data element may be communicated to a Data Requestor only if the Data Requestor's Information Request has been authenticated by an Independent Trust Authority indicating that the Data Requestor is trustworthy.

The Data Controller Agent further includes a Definitions database 76 storing information for dynamically deriving responses to Information Requests from data elements stored in the Data Vault 72. A Transaction Log 80 is provided for storing data receipts indicating information retrieved/disclosed and associated terms of use, etc.

The Data Controller Agent 70 also includes a Negotiation Engine 78 for receiving requests for information that specify terms of use of the requested data elements derived information, for comparing such information requests to rules stored in the Rules database 74 for deriving information in response to such requests based on definitions stored in the Definitions database 76 or elsewhere, and for determining whether to retrieve/disclose requested information or to counteroffer with acceptable terms for retrieval/disclosure of requested information based on the rules. The Negotiation Engine 78 operates as a process logically positioned between client-side web browser software 82 or e-mail software 84 and a third-party web page, e-mail or similar data servers/transmitters/requestors.

The Negotiation Engine 78 receives specially configured requests for information from Data Requestors (an “Information Request”). The Information Request identifies the information being requested and the purposes for which the requested information will be used. In effect, the Information Request provides a disclosure of contract-type terms regarding collection and use of information. An Information Request may have various forms. One such form is the form of an XML document described by a schema indicating types of information requested and the purposes for which the information will be used. Known XML standards and encryption may be used to create and deliver such an XML document, and to enhance trustworthiness of the Information Request. For example, the XML document may be delivered to the client device via HTTP transmission protocols; via an e-mail message; or via a Simple Object Access Protocol (“SOAP”) message such as the type well known for web services, such as Microsoft Corporation's NET XML web service. Alternatively, the Information Request may be carried as part of an e-mail message.

As shown in FIGS. 1 and 3, the system 10 includes a Data Requestor 20, such as a website, party sending e-mails, requesting and/or collecting information, etc. The Data Requestor 20 maintains a Tagged Data database 22 of data elements or other information (collectively “data elements”) received from Data Controllers (i.e. the Data Controller Agents of Data Controllers). The data elements in the Tagged Data database 22 are tagged in that additional information is stored in association with the data elements that indicates the terms under which the Data Controller agreed to disclosure of the data element(s). The terms may reflect the rules in a respective Data Controller's Rules database and/or the Notice, Choice, Access and Security presentation of the Information Request (or a similar schema based on the OECD principles or other scheme). Any future use of the data elements, either by the Data Requestor 20 or by Third Party Data Requestors 30, is performed in accordance with the terms stored in the tags. For this purpose, the tags preferably travel onward to any Third Party Data Requestors 30 so that conditions of use of data elements travel with the corresponding data elements so that use in compliance with the data elements may be ensured. In other words, continued use in accordance with the terms of the original disclosure “contract” is ensured. This may be particularly advantageous in the context of digital rights management or media management, e.g. to ensure that rights owners are compensated for each distribution of proprietary information/data.

In addition, the Data Requestor 20 has a Transaction Log 24 that stores a data receipt indicating data received from Data Controllers and/or data transmitted to Third Party Data Requestors 30. Such data receipts are similar in content to those described above with reference to the Data Controller Agent.

Additionally, the Data Requestor 20 has a Negotiation Engine 26 similar to that of the Data Controller's Negotiation Engine 78, as discussed above.

Third Party Data Requestors 30 also have similar Tagged Data databases 32, Transaction Logs 34 and Negotiation Engines 36, but communicate directly with the Data Requestors 20. By way of example, Third Party Data Requestors 30 may be marketing entities, corporate business partners, etc. of the Data Requestors 20.

The system 10 may further include an Independent Trust Authority and/or a Vault Custodian 50, as discussed below.

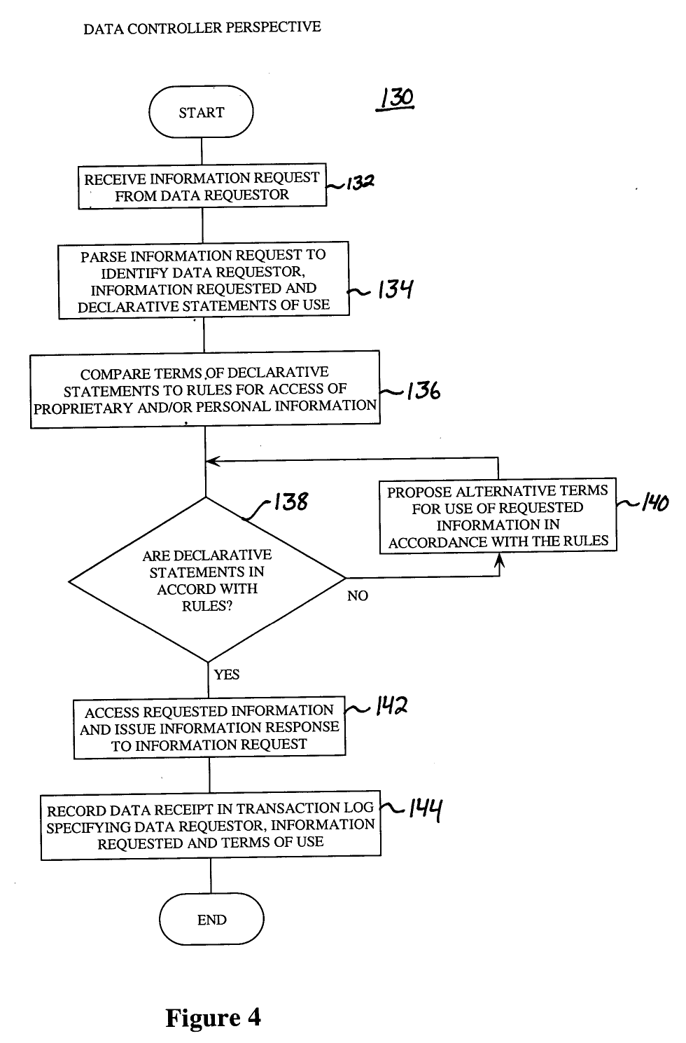

Referring now to FIG. 4, a flow diagram 130 of information exchange in accordance with an exemplary embodiment of the present invention is shown from a Data Controller's perspective. As shown in FIG. 4, the method of information exchange 130 begins with receipt of an Information Request from, a Data Requestor 20, e.g. via the communications network at the Negotiation Engine 78 of the Data Controller Agent 70 of the Data Controller's client device 60, as shown at step 132. For example, the Information Request may include a request for name, address, telephone number and credit card number data elements that are proprietary information stored in the Data Controller's Data Vault 72.

The Information Request may also indicate the intended use for the requested information, such as, for local use on the Data Controller's client device to personalize a web page, or to complete a request for transmission of information to the Data Requestor's website, web server, etc. to complete a transaction such as an e-commerce transaction or for an exchange of information for other purposes.

The Information Request may also provide notice of the party/entity requesting the information, the uses intended by the Data Requestor and identification of any third parties to which the Data Requestor may transfer the requested information, the uses intended by the third parties that may receive the requested information, an expiration date after which the information will be deleted and/or no longer used for the approved uses, statements of whether the information will be used as personally identifiable information or used anonymously in aggregated form for statistical purposes, etc. a notice of rights available to the Data Controller, a notice of oversight by an independent trusted third party (ITA), etc.

The Information Request may also set forth choice parameters, such as whether a reply to a request is mandatory or voluntary, an indication of consequences and failure to satisfy the request, a means of communication within the response to the request of choice or consent with respect to rights available defined in the notice section, and an indication whether or how a choice interface is provided that allows ongoing communication of rules by the Data Controller.

The Information Request may include access parameters indicating whether or how an access interface is provided to allow a Data Controller to have ongoing access by the Data Controller to information received from responses so that the Data Controller may view the information to contest its accuracy or completeness, update the data, cause deletion of the data, etc.

The Information Request may also include integrity or security parameters indicating a notice of measures used to protect security of data derived from the responses and/or a notice of measures used to protect the accuracy of data derived from the responses.

The Information Request may further include enforcement parameters indicating whether there is a notice of audits and certification of the requester indicating available remedies and consequences of failure of the Data Requestor to meet commitments, and information for providing access to an enforcement interface by which a data controller may access an Independent Trust Authority to address grievances with respect to the Data Requestor.

An Information Request may also indicate trust parameters including a level of trust verification required, e.g. no trust verification whereby the Data Controller's information is accepted as true, or higher levels of trust verification, whereby information and/or underlying data elements must be certified by an Independent Trust Authority such as TRUSTe, Verisign, an accounting or privacy consulting firm, or otherwise be authenticated.

Further, the Information Request may indicate whether an Independent Trust Authority has digitally signed, endorsed or validated the Information Request, e.g. to confirm that the notice of the Information Request complies with the actual request for data and/or that the information will be used in the manner disclosed, etc.

The Information Request may also provide parental control parameters to permit a parent to exercise control over a minor's online interactions and/or to prevent unauthorized disclosure by minors to block disclosure of personally identifiable information or other protected data from disclosure to the Data Requestor.

Referring again to FIG. 4, the Negotiation Engine 78 parses and interprets the Information Request and determines what information and/or which data elements are requested, and for what purposes. More specifically, the Information Request is parsed to identify the Data Requestor, the information requested, and any declarative statements of use carried by the Information Request indicating the intended uses/terms of use for the information requested, as shown at step 134.

The Negotiation Engine 78 ensures that data elements stored in the Data Vault 70 are accessed, retrieved and/or disclosed in response to an Information Request only if permitted by the rules of the Rules database 74 for the requested data elements. Accordingly, as shown at step 136, the Negotiation Engine 78 compares the terms of the declarative statement(s) of the Information Request to rules of the Rules database 74 that govern access of the Data Controller's proprietary and/or personal information. Accordingly, the Negotiation Engine 78 interprets the Information Request and checks the Information Request against the Rules database 74 and decides whether to retrieve and/or disclose data elements stored in the Data Vault 72.

The Negotiation Engine 78 determines whether the terms of the declarative statements of the Information Request indicating the uses/terms of use desired by the Data Requestor are in accord with the rules of the Rules database governing the permitted disclosure of the Data Controller's information, as shown at step 138. If the Negotiation Engine 78 determines that the they are not in accord, i.e. the rules do not permit disclosure under the terms carried by the Information Request, then the Negotiation Engine 78 may propose alternative terms for use of the requested information in accordance with the Data Controller's applicable rules, as shown at step 140, and it is determined whether agreement can be reached. This may involve comparison with alternative terms carried by the Information Request, or by communication with the Negotiation Engine 26 of the Data Requestor 20 originating the Information Request.

The Negotiation Engine 78 then accesses the requested information and issues an Information Response to the Information Request, as shown at step 142. The form of the response will depend upon the request. For example, if it is determined that the rules permit local use of the requested data elements, it may retrieve the requested data elements from the Data Vault 70 and pass them to the web browser 82, e-mail client 84 or an interpretive rendering engine for use thereby for display on the client device 60. If the Negotiation Engine 78 determines that the information may be disclosed, i.e. transmitted, to the Data Requestor 20 for use by the Data Requestor 20 in accordance with the rules of the Rules database 74, it does so or permits such transmission in the form of an Information Response.

Any Information Response transmitted from the Data Controller Agent's Negotiation Engine 78 to the Data Requestor's Negotiation Engine 26 may provide the requested information in the form of data elements as retrieved from the Data Vault 70. Alternatively, the Information Response may provide the requested information as it is dynamically derived from data elements stored in the Data Vault 70. For example, definitions defining logic or information (such as a URL for a dynamic lookup based on certain data elements) for deriving requested information may be stored in the Definitions database 76 of the Data Controller Agent 70. In this manner, a response may be provided without disclosing more information than is necessary. For example, an Information Request may request the Data Controllers current age, and a definition may specify that the current age may be calculated from birthdate data stored in the Data Vault and current date data. Accordingly, a Information Request for a current age received by the Negotiation Engine may result in returning of a suitable response, although no data elements identifying the Data Controller's age are stored in the Data Vault because a response to the request may be dynamically created.

While it may be easy to determine in advance definitions for a number of likely Information Requests, it is unlikely that all possible Information Requests can be anticipated. Alternatively, the Information Request may encapsulate a definition and identify data elements required to be retrieved to implement the definition and satisfy the Information Request. Alternatively, an Information Request may reference an external resource, such as a remotely stored definitions database, such as a Definitions Database 42 maintained by an Independent Trust Authority 40.

If, either initially or after negotiation, the declarative statements are in accord with the rules such that data elements are retrieved from the Data Vault 70, either for local use or for disclosure/transmission to a third party, then the Negotiation Engine 78 records a data receipt in the Transaction Log 80 of the Data Controller Agent 70 that specifies the Data Requestor, information requested, and agreed upon terms of use, as shown at step 144. The Transaction Log is a repository for data receipts, such as a database or memory of a computer. Optionally, the information of the data receipt may be encoded to ensure non-repudiation of the response. In addition, the Data Requestor may send a data receipt to the Data Controller, which is stored in the Transaction Log of the Data Controller Agent, and the Data Requestor 20 may store a similar data receipt in its own Transaction Log 24.

In elaboration of steps 138 and 140 above, consider that if the Negotiation Engine 78 determines that it cannot disclose the requested data elements under the terms of the Information Request because the terms conflict with the rules for such data elements, the Negotiation Engine 78 may refuse disclosure of the requested information. Alternatively, the Negotiation Engine 78 may communicate alternative terms, in accordance with those set forth in the Rules database 74, under which the requested information will be disclosed such that the alternative terms may be considered and accepted or rejected by the Data Requestor 20. For example, if the Information Request requests the Data Controller's name data element for the purpose of transmitting the Data Controller's name data element to a Third Party Data Requestor, and the Data Controller's preferences do not permit such use, the Negotiation Engine's Information Response may so indicate. By way of further example, consider an individual Data Controller wanting to subscribe to a newsletter Data Requestor, but not wanting to allow its name to be used in onward transfer (the newsletter's default usage rights); a subscription can still be effected by the Negotiation Engine if the newsletter Data Requestor allows for registrations of users who have forbidden onward transfer as a preference.

By way of example, consider an individual navigating the Web and visiting websites, and that upon reaching a given website, the website assumes the role of Data Requestor by transmitting an Information Request to the individual's client device in the form of an XML document. The Information Request is intercepted by the Negotiation Engine of the Data Controller Agent before any information is retrieved or disclosed from the Data Controller's Data Vault.

In this example, the individual client visits the Amazon.com website with an intent to purchase a book. The Information Request of this example provides notice, via the XML document, that any information collected from the Data Controller will be used locally, at the Data Controller's client device, for customization of web pages displayed via the client device, and that a refusal to disclose the requested information will result in the display of a generic, rather than a customized, web page. In this example, the Information Request requests data elements indicating an age, gender, interests and financial information of the individual Data Controller. The Negotiation Engine of the Data Controller Agent receives and interprets this Information Request, and checks the Rules database of the Data Controller Agent to determine the terms on which the Data Controller is agreeable to disclose age, gender, interest and financial information elements stored in the Data Vault as set forth in rules associated with such data elements. The Negotiation Engine determines that the rules permit disclosure for such use, i.e. local use for customization purposes, and then such data elements are retrieved from the Data Vault and used by the Negotiation Engine, which may include a Rendering Engine, to transform the web page source file transmitted from Amazon.com's web server and to render the web page via the user's web browser in a customized manner in view of the age, gender, interest and financial information data elements retrieved from the Data Vault in a manner specified by the web page and performed by the Rendering Engine.

It should be noted that certain information may be appropriate for certain uses, but not others, e.g. collection and use of financial account number information for internal marketing or inbound web-banner marketing purposes, but not for outbound direct mail or telemarketing purposes under the Gramm-Leach Bliley Act pertaining to financial privacy. By way of further example, web click-stream data may be used to identify preferences or desired products and to subsequently be able to use such information at a point-of-purchase in a store or on a telephone by a sales representative to customize purchase suggestions/advice or to identify/anticipate upsell product opportunities.

Suppose, by way of further example, that birth date data elements are stored in the Data Vault but that an age is requested in the Information Request. The Negotiation Engine may determine this and identify a definition for determining an age from a birth date, either in the Definitions database of the Data Controller Agent, or by a definition encapsulated in the Information Request, or by a Definitions database stored elsewhere but accessible to the Data Controller Agent (such as at the Independent Trust Authority). The Negotiation Engine then determines age, according to the definitions, from the birth date data element retrieved from the Data Vault, but then uses only the age to customize the web page in an anonymous and automated fashion. In another example, if the Information Request indicated that the age information would to be transmitted to the Data Requestor, the Negotiation Engine discloses the age to the Data Requestor, but not the birth date data elements retrieved from the Data Vault.

By way of further example, if the Data Requestor sends an Information Request requesting an age, and indicating that it intended to disclose the age to Third-Party Data Requestors, and the Negotiation Engine referenced the Rules database and determined that the Data Controller will permit disclosure of age to a Data Requestor, but not subsequent disclosure of age from the Data Requestor to Third-Party Data Requestors, the Negotiation Engine will respond by sending counteroffer information to the Data Requestor indicating that the Data Controller is agreeable to disclose age information for use by the Data Requestor, but not for use for disclosure to Third-Party Data Requestors. The Negotiation Engine of the Data Requestor may then choose to accept the Data Controller's terms, reject them, or propose counteroffer terms. If the Data Requestor agrees to accept the age on the counteroffer terms, the Negotiation Engine discloses age information to the Data Requestor. As described above, disclosed information is stored in the tagged data database of the Data Requestor indicating the Data Controller's age, and the terms of use indicating that age may be used by the Data Requestor but not transmitted to a Third-Party Data Requestor. Subsequent requests for the Data Controller's information from Third-Party Data Requestors to the Data Requestor result in nondisclosure of the Data Controller's age information from the Data Requestor to the Third-Party Data Requestor.

Consider by way of further example that a Data Requestor has requested an e-mail address of the Data Controller for disclosure to Third-Party Data Requestors, and that the Negotiation Engine has checked the Data Controller rules and determined, at the time of the request, that the Data Controller permitted disclosure of e-mail address information to the Data Requestor with permission that the Data Requestor may disclose the e-mail address to Third-Party Data Requestors for the purpose of receiving commercial advertisements. Consider further that such e-mail address information and permission information were stored in the Tagged Data database of the Data Requestor and subsequently transmitted and stored in the Tagged Data database of a Third-Party Data Requestor. However, at a later time, the Data Controller may become overwhelmed with advertisements for commercial offers via its e-mail address and choose to stop all further use of its e-mail address to receive commercial advertisements (from a selected one, a group, or all Data Requestors or Third Party Data Requestors that directly or indirectly received and stored information regarding the Data Controller). Accordingly, the Data Controller may use the access interface, as described further below, to check the Transaction Log of the Data Controller Agent, to identify a data receipt indicating transmission of its e-mail address to a Data Requestor, and subsequently transmit information to the Data Requestor to access the tagged data of the Data Requestor and change the permission associated with its e-mail address to prevent receipt of commercial advertisements via its e-mail address, e.g. to revoke consent. Additionally, by the access interface, the Data Controller may access the Data Requestor's Transaction Log to determine that the Data Requestor has transmitted the Data Controller's e-mail address and permission information to a Third-Party Data Requestor via the access interface, the Data Controller may also access the tagged data database of the Third-Party Data Requestor to change the permission for use of its e-mail address to prevent receipt of commercial advertisement by its e-mail address. It will be appreciated that this process may occur in an automated fashion such that the Data Controller may simply update the permission for use of its e-mail data element and that in automated fashion that permission, and information in various Tagged Data database is updated in the Data Controller's preferences, in the Tagged Data database Data Requestors who have received the information, and in the Tagged Data databases of all Third-Party Data Requestors having received such information. In this manner, the Data Controller maintains control over its disclosed data, even after initial disclosure.

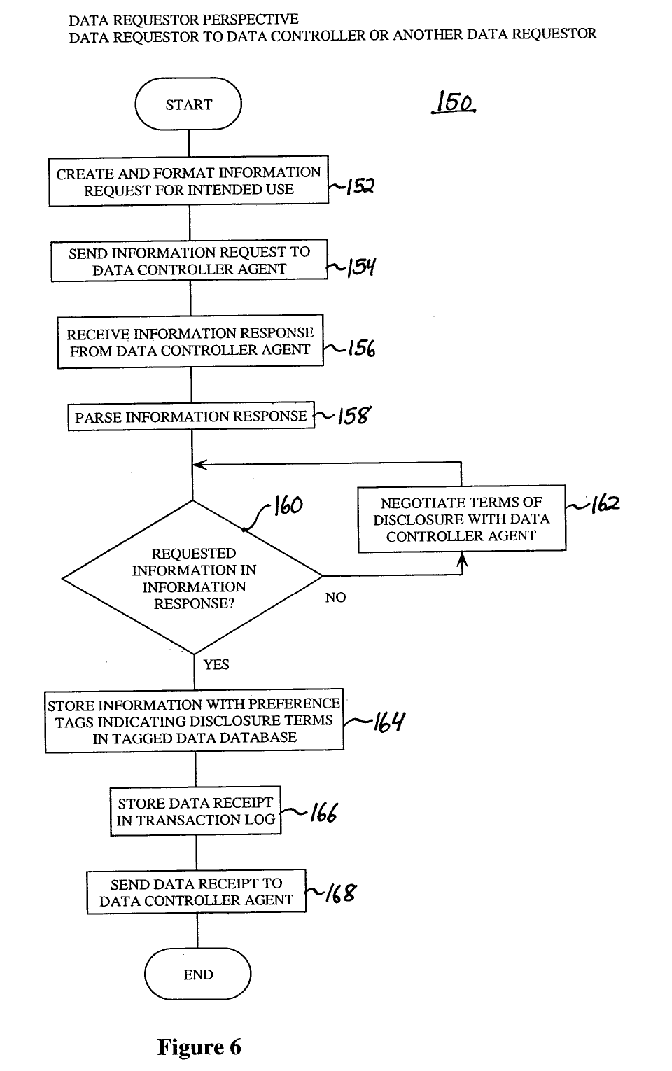

FIG. 6 shows a flow diagram 150 illustrating information exchange of FIG. 4 from the perspective of a Data Requestor 20 as shown in FIG. 6. The method starts with creation and formatting of an information request for transmission to the negotiation engine 78 with the Data Controller agent 70 of a client device, as shown in step 152. The information request beyond the format discussed above.

Next, the information request is sent to the Data Controller agent 70 of a client device, as shown in step 154. After the negotiation engine 78 of a client device 60 prepares an information response for transmission to the Data Requestor, the Data Requestor then receives an information response from the Data Controller agent 70, as shown in step 156. The negotiation engine 26 of the Data Requestor 20 then parses the information response as shown in step 158. If the requested information is not contained in the information response then the negotiation engine 26 of the Data Requestor may negotiate terms of disclosure with the Data Controller agent 70 to obtain the request information, as shown in steps 160 and 162 of FIG. 6. Once the requested information is received via an information response, the Data Requestor stores the requested information in the tagged data database 22, as shown at step 164. The requested information is stored in association with preference tags indicating the agreed upon terms of use/disclosure under which the requested information was obtained. Optionally, a data receipt may be stored in the Data Requestor transaction log 24 and or sent to the respective Data Controller agent 70 for storage in its transaction log 80, as shown at steps 166 and 168.

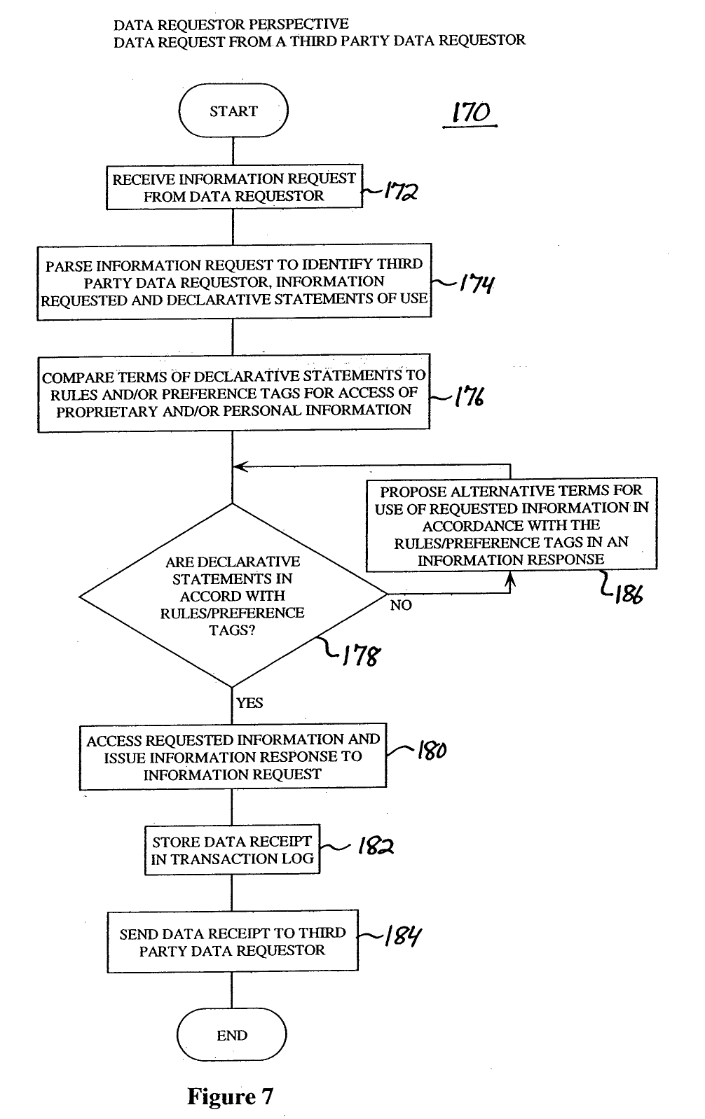

FIG. 7 shows a flow diagram 170 illustrating exemplary information exchange between a Data Requestor 20 and a Third-Party Requestor 30. As shown in FIG. 7, a Data Requestor 20 may receive an information request from a Third-Party Data Requestor, as shown at step 172. The Data Requestor then parses the information request to identify the Third-Party Data Requestor, information requested and declarative statements of use contained in the information request, as shown at step 174. Accordingly this and following steps are analogous to communications between the Data Requestor and the Data Controller agent 70. Accordingly, terms of use etc., from the information request are compared to rule and/or preference tags for the associative information that are stored in the Tagged Data database 22 of the Data Requestor 20, as shown at step 176. If the declarative statements in the information request from the Third-Party Data Requestor are in accord with the rules for preference tags in the Tagged Data database of the Data Requestor 20, then the Data Requestor may access the information and issue an information response recorded data receipt in its Transmission Log 24 and/or send a data receipt to the Data Requestor to the Third-Party Data Requestor 30 as shown at steps 178-184. Alternatively if the declarative statements are not in rules for reference tags for the data as stored by the Data Requestor, then the Third-Party Data Requestor may propose alternative terms and/or negotiate the terms between the negotiation engines 26, 36 of the Data Requestor 20 and Third-Party Data Requestor 30 until agreement is reached or is determined to be unreachable as shown at steps 178 and 186. Accordingly, the negotiation process between the Third-Party Data Requestor and the Data Requestor is some what similar to the negotiation and disclosure process between the Data Requestor and client device and is noted that the preferences and/or rules governing the use and disclosure of information from the Data Controller travel to the Data Requestor and are used to determine whether or not such information can be passed onto any Third-Party Data Requestors.

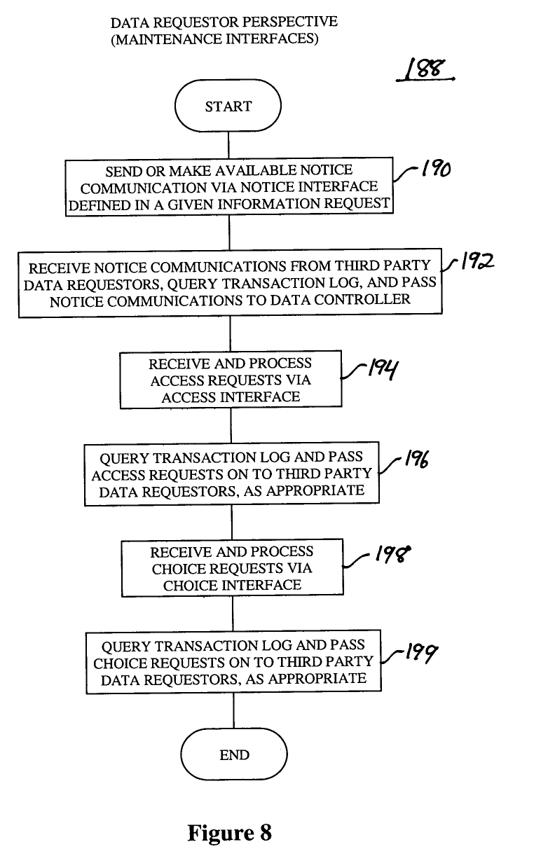

Referring to FIG. 8, it is noted from the flow diagram 188 that access notice and choice etc., information communicate to a Data Requestor by a Data Controller may be passed onto Third-Party Data Requestors that have received information from the Data Requestor e.g., after referring to the transaction log 24 of the Data Requestor 20, as shown at steps 190-199. Accordingly when a Data Controller uses a maintenance interface to modify notice access choice etc., parameters with a Data Requestor to which his Data Controller agent has forwarded data, those updates, changes etc., are passed onward to any Third-Party Data Requestor so that the Data Controllers updated data and/or preferences are associated with data at its location to ensure continued use in accordance with the Data Controller's wishes.

Maintenance Interfaces

Preferably, Maintenance Interfaces are provided for use by the Data Controllers to provide for ongoing communication between the Data Controller and Data Requestors/Third Party Data Requestors so that the Data Controller may maintain control over its proprietary data. By way of example, such interfaces may be provided by SOAP, SMTP, HTTP or other protocols, or e-mail technologies. For example, the interface may be provided via a secure website.

The Maintenance Interfaces provide the Data Controller with the ability, following the initial collection of information by a Data Requestor, to access, update, modify and otherwise interact with the information collected from it, and associated permitted terms of use, etc. and/or the Data Requestors having collected such information. In the example of a system for use for personal privacy purposes and to comply with Fair Information Practice Principles, the Maintenance Interfaces include at least four logical components related to the principles, namely a Notice Interface, an Access Interface, a Choice Interface, and a Security Interface as well as an Enforcement Interface.

The Notice Interface provides the Data Controller with ongoing communications from the Data Requestor(s), on an ongoing basis, to communicate information regarding data and/or the data request/data response transaction. For example, the terms of use for particular information disclosed by a Data Controller to a Data Requestor might require that the Data Requestor provide notice to the Data Controller upon each subsequent transfer of such information, or any portion thereof, to a Third Party Data Requestor. The Notice Interface enables the Data Request to comply with such terms by providing a mechanism for providing such notice.

The Access Interface provides the Data Controller with ongoing communication to the Data Requestor to determine the extent and accuracy of data stored in the Data Requestors' and, directly or indirectly, any Third Party Data Requestors', databases.

The Choice Interface provides the Data Controller with available choice options that may be determined by the rights of the Data Controller under the terms of the original Information Request/Response contract, or by legal definitions of rights of the respective parties. For example, the Choice Interface may permit the Data Controller to change its decision about consenting to receiving newsletters and/or sharing of the Data Controller's e-mail address with their third party marketing partners. By way of further example, a Data Controller may use the Choice Interface to revoke consent to receive such offers by causing removal of the Data Controller's name from a mailing database, or changing the tag on the Data Controller's e-mail address data kept at the newsletter company to the discontinue permission for disclosing the Data Controller's e-mail address to third parties, but to permit the Data Controller to continue to receive the newsletter. By way of further example, the Data Controller may use the Choice Interface to change permissions regarding use of its previously disclosed information to stop it from receiving all subject-related newsletters/e-mail messages.

The Security Interface provides the Data Controller with online communication to specify various levels of security measures, e.g. to require encrypted or other specific-level of security during storage, including regulated standards (e.g., the Security Requirement under Health Insurance Portability and Accountability Act of 1996).

The Enforcement Interface provides the Data Controller with ongoing communication to an appropriate party (i.e., Independent Trust Authority, regulatory agency, arbitration board, etc.) for enforcement of contract terms, resolution of disputes, redress of grievances, etc.

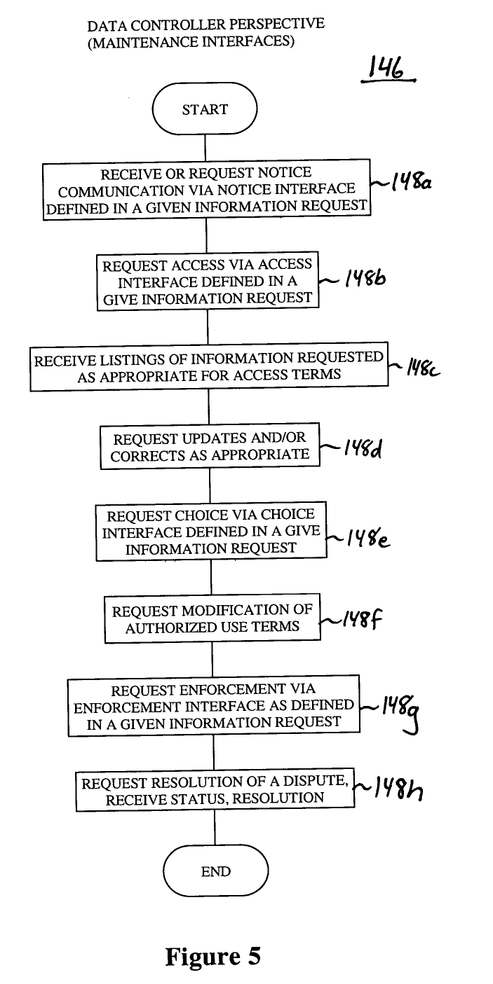

Referring now to FIG. 5, an exemplary flow diagram 146 is shown that illustrates that a maintenance interface is provided, e.g. via a website or via e-mail communication, to permit a Data Controller to receive or request notice communication, to request access to gathered information, to receive listing of information requested as appropriate for access terms, to request updates and/or make corrections, to request choice and modify authorized terms or use, and to request enforcement to request resolution of a dispute, receive status and resolution information, etc., as shown at steps 148a-148h.

Independent Trust Authority

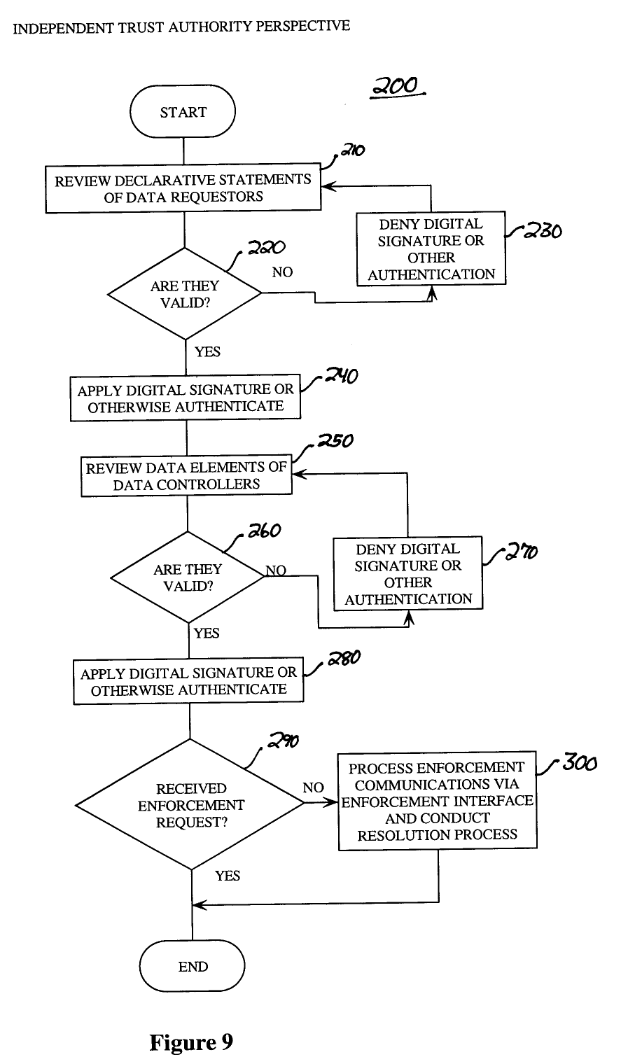

While the present invention enables self-regulatory trust assurances, use of an Independent Trust Authority 40 provides verifiable historical compliance with the information collection, use, storage and disclosure terms and conditions for each data element, as appropriate. To ensure that Data Requestors and Data Controllers are honest and fair in collecting and/or disclosing information, it is preferable to provide an Independent Trust Authority, or more specifically a hardware and/or software-implemented process acting on behalf thereof (“ITA”). TRUSTe, Verisign, accounting firms providing auditing services and privacy consulting firms are somewhat analogous to the ITA. The ITA is an independent party that certifies Data Requests and/or accuracy of data elements to lend credibility and trust to parties and transactions in accordance with the present invention. For example, an ITA may provide verification services for verifying certain data elements stored by a Data Controller. Once satisfied that the data element is accurate, the ITA may digitally sign the data element or provide other authentication to put other parties on notice that the data element has been verified by the ITA, as shown at steps 210-240 of FIG. 9. In the case of digital signatures, the digitally signed data element may be stored in the Data Vault so that any Data Requestors that request and receive that data element are made aware that it has been verified by the ITA. In this manner, Data Requestors can consider more trustworthy any data elements marked as having been approved and/or endorsed by an ITA. Suitable digital signature, encryption and other verification and authentication technologies are well known in the art, and any suitable technology may be employed for this purpose. Alternatively, the ITA may communicate directly with the Data Requestor to verify data elements dynamically, e.g. through an Information Request/Information Response transaction with an ITA rather than a Data Controller.

Additionally, the Negotiation Engine may then make trusted assertions in the form of digitally signed and/or ITA verified or endorsed dynamically derived responses when the underlying data elements are ITA verified. Optionally, the definition for dynamically deriving information from stored data elements may be similarly verified to establish appropriate trustworthiness of the trusted assertion.

Similarly, the ITA may investigate and verify Data Requests of Data Requestors to ensure that the Data Request includes full and accurate disclosure of the data elements being collected, the purposes for which the data elements are used, etc., as shown at steps 210-240 of FIG. 9. In this manner, Data Collectors can consider more trustworthy any Data Requests marked as having been approved and/or endorsed by an ITA. In some circumstances, endorsement by an ITA may be a condition for disclosure in the Data Controller's Rules database.

The ITA may play a role in the Enforcement interface by receiving complaints from aggrieved parties and/or resolving such complaints, which may include revocation of endorsements by the ITA, as shown at steps 290-300 of FIG. 9. The Data Controller may communicate directly with the ITA to verify Data Requests dynamically.

In order to provide for a trusted and practical infrastructure, it may be desirable and/or necessary to create a Central Registry of ITAs and certain other data. For example, the Fair Information Practice Principles require that there be no secret repositories of PII data. As such, a central registry of repositories may be appropriate. Due to the mechanics of ‘namespaces’ related to schemas and the standardized definition and communication of data, a central registry may also be necessary for technical reasons. This is analogous to the central registry model employed by the Domain Name Service (DNS) infrastructure that enabled resolution of names (ie, xyz.com) to network addresses.

Vault Custodian for Remote Access

A Vault Custodian 50 (or more specifically a hardware and/or software-implemented process acting on behalf thereof) may be employed in a system in accordance with the present invention to enhance remote access from a variety of devices, to provide location transparency, and to provide a “backup” of data storage. For example, the Data Collector's Data Vault may be stored centrally, e.g. in a network accessible location, and accessed remotely as permitted by a Vault Custodian who may, for example, transmit the Data Vault rules, Transaction Log, Negotiation Engine, etc. from the centralized location to a particular client device upon authenticated access, e.g. via a single sign-on mechanism or service such as Microsoft Passport, Liberty Alliance, etc., e.g. via a chip card for mobile telephones and PDAs, from a particular user using the given device. In this manner, for example, an individual may access its data from shared computers, mobile devices, etc., as well as from its own PC. By way of example, the Negotiation Engine and other Data Controller Agent elements may be transferred to the PC or other client device currently used by the Data Controller, and reside, e.g. in a web browser, as a JAVA application, etc. The Data Controller Agent components and/or information may be decrypted using a decryption key, etc. to access the Data Controller's Data Vault, etc. In this manner one can obtain the full benefit of the Data Controller Agent from any client device. In one embodiment, the Vault Custodian has no access whatsoever to information stored and/or managed by Data Controller Agents and Data Vaults, but rather simply permits access to such Data Controller Agents and Data Vaults. In an alternative embodiment, Vault Custodians have access and act on behalf of Data Controllers, at least for certain specified transactions, as desired.

Monetary Transactions

It will be appreciated that the invention is applicable to exchange of value transactions, e.g. to provide that a Data Controller is paid for disclosure, collection, use, etc. of information, such as personally identifiable information in the privacy context or proprietary information in the digital rights management context. For example, the rules may provide for an actual or minimum payment for disclosure of the requested information, and the Information Request may provide for a minimum or actual payment for the requested information, disclosure of information is then determined by the Negotiation Engine similar to that described above. Payments may be tracked, credited, etc. by the system.

Having thus described particular embodiments of the invention, various alterations, modifications, and improvements will readily occur to those skilled in the art. Such alterations, modifications and improvements as are made obvious by this disclosure are intended to be part of this description though not expressly stated herein, and are intended to be within the spirit and scope of the invention. Accordingly, the foregoing description is by way of example only, and not limiting. The invention is limited only as defined in the following claims and equivalents thereto.

What is claimed is:

1. A method for exchanging information via a communications network, the method comprising:
receiving, via the communications network, an information request from a data requestor, the information request requesting information controlled by a data controller, data elements relating to the requested information being stored in a data repository controlled by the data controller, the information request comprising a statement setting forth parameters relating to collection of the requested information by the data requestor;
referencing a rule specifying parameters relating to permissible retrieval of a requested data element from the data repository in response to the information request, the rule having been established for the data element by the data controller;
if the collection parameters are in accord with the retrieval parameters, retrieving the data element from the data repository and using it in accordance with the information request; and
if the collection parameters are not in accord with the retrieval parameters, responding to the information request with an offer to retrieve the data element for use in accordance with the rule.

2. The method of claim 1, further comprising:
parsing the information request to identify any data elements relating to the requested information, and to identify the statement setting forth the collection parameters; and
comparing the collection parameters to the parameters of the rule to determine whether they are in accord.

3. The method of claim 1, wherein using the data element in accordance with the information request comprises using the data element to customize a display of information on a client device storing the data repository.

4. The method of claim 1, wherein using the data element in accordance with the information request comprises using the data element to derive the requested information according to a definition stored in a definitions database.

5. The method of claim 1, wherein using the data element in accordance with the information request comprises transmitting the data element via a communications network.

6. The method of claim 5, wherein the data element is transmitted to the data requestor.

7. The method of claim 6, further comprising permitting the data controller to access data collected by the data requestor via a maintenance interface.

8. The method of claim 7, further comprising permitting the data controller to modify any data collected by the data requester via the maintenance interface.

9. The method of claim 7, further comprising permitting the data controller to specify alternative parameters for data already collected by the data requestor via the maintenance interface.

10. The method of claim 9, further comprising transmitting the alternative parameters for such data to any third party data requesters to which the data requestor has previously transmitted such data.

11. The method of claim 10, further comprising:
storing a data receipt in a transaction log at the client device, the data receipt identifying the data requester, the data element retrieved from the data repository, and the applicable parameters.

12. The method of claim 1, wherein the requested information relates to an individual that is a data subject, and wherein the data controller is the data subject.

13. A method for exchanging information via a communications network, the method comprising:
a data requestor sending, via the communications network, an information request to a data controller, release of the requested information being controlled the data controller, a corresponding data element relating to the requested information being stored in a data repository controlled by the data controller, the information request including a declarative statement setting forth parameters relating to collection of the requested information by the data requester;
the data requestor receiving, via the communications network, a response to the information request from the data controller, the response including the requested information; and
the data requestor storing the requested information in a memory, the requested information being stored in association with parameters representing terms under which the data controller agreed to release the requested information to the data requestor.

14. The method of claim 13, the response further comprising alternative parameters relating to collection of the requested information by the data requestor, the alternative parameters being in accord with a rule specifying parameters relating to permissible retrieval of the data element from the data repository in response to the information request, the rule having been established for the data element by the data controller.

15. The method of claim 14, wherein the alternative parameters are stored by the data requestor in the memory in association with the requested information.

16. The method of claim 14, further comprising:
the data requester receiving a subsequent information request from a third party data requestor, the subsequent information request requesting information controlled by the data controller, the requested information being stored in the memory controlled by the data requester;
parsing the subsequent information request to identify information requested and a respective declarative statement setting forth parameters relating to collection of the requested information by the third party data requestor;
comparing the collection parameters to the parameters stored by the data requestor in the memory in association with the requested information, the parameters relating to permissible retrieval of the requested information from the memory in response to the subsequent information request, the rule having been established by the data controller;
if the collection parameters are in accord with the parameters stored by the data requestor, retrieving the requested information from the memory and using it in accordance with the subsequent information request; and
if the collection parameters are not in accord with the parameters stored by the data requester, responding to the subsequent information request with an offer to retrieve the requested information for use in accordance with the parameters.

17. A method for authenticating a request for information exchange, the method comprising and independent trust authority performing the steps of:
reviewing a data requestor's information request, the information request relating to retrieval of a data element, the information request comprising a statement providing notice of the data element requested;
comparing the statement of the data element requested to the data element or data elements requested for retrieval by the information requested; and
authenticating the information request if the statement provides accurate notice of the data element or data elements requested.

18. The method of claim 17, wherein the authenticating comprises applying a notice that the independent trust authority has authenticated the information request.

19. The method of claim 17, wherein the authenticating comprises applying a digital signature indicating authenticating by the independent trust authority.

20. A method for exchange of information via a communications network, the method comprising the steps of:
transmitting, to a data controller, an information request requesting information controlled stored in a data repository controlled by the data controller, the information request including proposed parameters relating to use of the requested information;
negotiating with the data controller, if necessary, to obtain agreement as to acceptable parameters relating to use of the requested information;
receiving, from the data controller, the requested information;
storing the requested information in association with the acceptable parameters relating to use of the requested information; and
limiting use of the requested information to use in accordance with the acceptable parameters.

21. The method of claim 20, further comprising:
permitting the data controller to subsequently alter the acceptable parameters stored by the data requestor, the method further comprising limiting future use of the requested information to use in accordance with the altered acceptable parameters.

22. The method of claim 20, further comprising:
transmitting the requested information relating to the data subject to a third party data requester only if the third party data requestor agrees to make use of the requested information in accordance with the acceptable parameters.

23. The method of claim 20, wherein the negotiation is performed automatedly by at least one software-implemented negotiation engine.
